(19) United States
(12) Patent Application Publication
(10) Pub. No.: US 2026/0128540 A1
(43) Pub. Date: May 7, 2026

(54) EXTENDED CONNECTOR CONTACT FOR MEMORY DEVICES

(71) Applicant: Sandisk Technologies, Inc., Milpitas, CA (US)

(72) Inventor: Vishwajith Poojari, Udupi (IN)

(21) Appl. No.: 18/939,996

(22) Filed: Nov. 7, 2024

(51) Int. Cl. H01R 12/72; H01R 13/658; H05K 1/18

(52) U.S. Cl. CPC H01R 12/728; H01R 13/658; H05K 1/18; H05K 2201/10159

(57) ABSTRACT

An extension portion of a solid state memory device printed circuit board provides additional ground shielding. In one example, the printed circuit board includes a main body and a connector contact portion at a first end of the main body. The connector contact portion includes pins and an extension portion that provides ground shielding to the pins. Ground pins may be connected to the extension portion by through hole vias. The connector contact portion may be connected to an SFF-8639 port.

### BACKGROUND

This application relates generally to connectors for electronic devices, and more specifically, to a connector footprint and printed circuit board extension for memory devices.

Electronic devices, such as solid state memory devices (“SSDs”), may utilize connectors, such as PCIe Gen4 and Gen5 U.2/U.3 (SFF-8639) connectors for meeting PCIe Gen4 and Gen5 product compliance standards. In particular, these connectors pass PCIe-SIG mandated insertion loss, return loss, and crosstalk specifications to provide reliable data transmission at high speeds.

### SUMMARY

Complex or large-scale memory and/or server systems may have many electronic devices, such as SSDs. However, board outlines of present Gen4 and Gen5 U.2 and U.3 enterprise SSD drives at the connector printed circuit board (PCB) contact area restrict the return current and impede shielding of connector contacts pads. Examples described herein provide a connector PCB contact area that extends beyond previous connector areas and provides additional current paths for ground pins, allowing for improved current flow and shielding without disturbing connector placement and mating.

In one embodiment, a solid state memory is described. The solid state memory includes a printed circuit board for a solid state drive. The printed circuit board includes a main body and a connector contact portion at a first end of the main body. The connector contact portion includes a plurality of pins and an extension portion that provides ground shielding to the plurality of pins.

In another embodiment a solid state memory device (SSD) connector is described. The connector includes a connector contact portion. The connector contact portion includes a plurality of pins and an extension portion that provides ground shielding to the plurality of pins. The SSD connector is one of a U.2 connector and a U.3 connector.

In another embodiment, an SFF-8639 connector for a solid state memory device (SSD) is described. The connector includes an extension portion extending beyond a plurality of pins. The plurality of pins are integrated in a connector contact portion of the connector. The extension portion is an extension of the connector contact portion. The extension portion provides ground shielding to the plurality of pins.

Various aspects of the present disclosure provide for improvements in memory devices. The present disclosure can be embodied in various forms. The foregoing summary is intended solely to give a general idea of various aspects of the present disclosure and does not limit the scope of the present disclosure in any way.

### BRIEF DESCRIPTION OF THE DRAWINGS

FIG. 1 is a block diagram illustrating one example of a system including a data storage device, according to some embodiments.

FIG. 2 is a diagram illustrating a PCB of a comparative data storage device.

FIG. 3 is a diagram illustrating a connector contact area of the PCB of FIG. 2.

FIG. 4 is a diagram illustrating a plan view of the connector contact area of FIG. 3 overlaid with the existing U.2 or U.3 connector footprint and ground connectivity.

FIG. 5 is a diagram illustrating a plan view of the connector contact area of FIG. 3 showing the inner reference ground connection voiding and via stitching.

FIG. 6 is a diagram illustrating an example PCB of a data storage device with an extension portion, according to some embodiments of the present disclosure.

FIG. 7 is a diagram illustrating the extension portion in a connector contact area of the example PCB of FIG. 6, according to some embodiments of the present disclosure.

FIG. 8 is a diagram illustrating a connector adjacent to the extension portion in the connector contact area of the example PCB of FIG. 6, according to some embodiments of the present disclosure.

FIG. 9 is a diagram illustrating a plan view of the connector contact area of FIG. 7 with a connector footprint and ground connectivity, according to some embodiments of the present disclosure.

FIG. 10 is a diagram illustrating a plan view of the connector contact area of FIG. 7 with inner reference ground connection voiding and via stitching, according to some embodiments of the present disclosure.

FIG. 11 is a chart illustrating an acceptable operating region for insertion losses according to the PCIE5 SFF-8639 SI Specification.

FIG. 12 is a chart illustrating an acceptable operating region for return losses according to the PCIE5 SFF-8639 SI Specification.

FIG. 13 is a chart illustrating an acceptable operating region for troublesome near-end cross-talk according to the PCIE5 SFF-8639 SI Specification.

FIG. 14 is a chart illustrating an acceptable operating region for troublesome far-end cross-talk according to the PCIE5 SFF-8639 SI Specification.

FIG. 15 is chart illustrating a plot of the frequency domain results of a comparative PCIe Gen5 U.2 SFF-8639 connector without the extension portion.

FIG. 16 is chart illustrating a plot of the frequency domain results of a U.2 SFF-8639 connector with the extension portion, according to some embodiments.

### DETAILED DESCRIPTION

In the following description, numerous details are set forth, such as data storage device configurations, and the like, in order to provide an understanding of one or more aspects of the present disclosure. It will be readily apparent to one skilled in the art that these specific details are merely exemplary and not intended to limit the scope of this application. The following description is intended solely to give a general idea of various aspects of the present disclosure and does not limit the scope of the disclosure in any way. Furthermore, it will be apparent to those of skill in the art that, although the present disclosure refers to NAND flash, the concepts discussed herein are applicable to other types of solid state memory, such as NOR, PCM (“Phase Change Memory”), ReRAM, etc. Those of skill in the art also will realize that although the disclosure refers to a substrate used in a data storage device, the disclosure may apply to substrates used in other types of electronic devices. The disclosure applies to both substrates and printed circuit boards used in electronic devices. Further, although specific examples disclose memory devices, it will be understood by those of skill in the art that the inventive concepts disclosed herein may be applied to other types of electronic devices that are assembled using a printed circuit board.

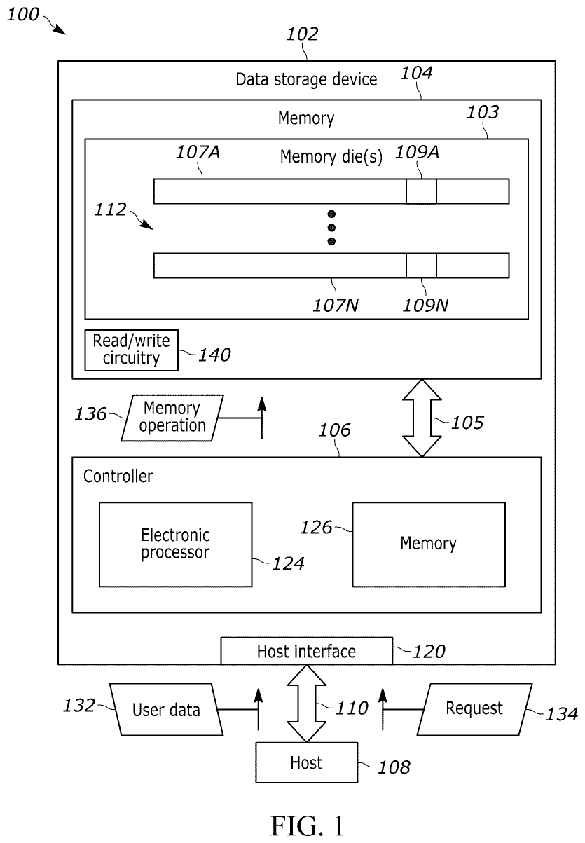

FIG. 1 is a block diagram of one example of a system 100 that includes a data storage device 102 in communication with a host device 108. The data storage device 102 includes a memory device 104 (e.g., non-volatile memory) that is coupled to a controller 106.

One example of the structural and functional features provided by the controller 106 are illustrated in FIG. 1. However, the controller 106 is not limited to the structural and functional features provided by the controller 106 in FIG. 1. The controller 106 may include fewer or additional structural and functional features that are not illustrated in FIG. 1.

The data storage device 102 and the host device 108 may be operationally coupled with a connection (e.g., a communication path 110), such as a bus or a wireless connection. In some examples, the data storage device 102 may be embedded within the host device 108. Alternatively, in other examples, the data storage device 102 may be removable from the host device 108 (i.e., “removably” coupled to the host device 108). As an example, the data storage device 102 may be removably coupled to the host device 108 in accordance with a removable universal serial bus (USB) configuration. In some implementations, the data storage device 102 may include or correspond to an SSD, which may be used as an embedded storage drive (e.g., a mobile embedded storage drive), an enterprise storage drive (ESD), a client storage device, or a cloud storage drive, or other suitable storage drives.

The data storage device 102 may be configured to be coupled to the host device 108 with the communication path 110, such as a wired communication path and/or a wireless communication path. For example, the data storage device 102 may include an interface 120 (e.g., a host interface) that enables communication with the communication path 110 between the data storage device 102 and the host device 108, such as when the interface 120 is communicatively coupled to the host device 108. In some embodiments, the communication path 110 may include one or more electrical signal contact pads or fingers that provide electrical communication between the data storage device 102 and the host device 108.

The host device 108 may include a processor and a memory. The memory may be configured to store data and/or instructions that may be executable by the processor. The memory may be a single memory or may include one or more memories, such as one or more non-volatile memories, one or more volatile memories, or a combination thereof. The host device 108 may issue one or more commands to the data storage device 102, such as one or more requests to erase data at, read data from, or write data to the memory device 104 of the data storage device 102. For example, the host device 108 may be configured to provide data, such as user data 132, to be stored at the memory device 104 or to request data 134 to be read from the memory device 104. The host device 108 may include a mobile smartphone, a music player, a video player, a gaming console, an electronic book reader, a personal digital assistant (PDA), a computer, such as a laptop computer or notebook computer, a server, such as a host data center server, a device using a U.2 or U.3 plug connector, any combination thereof, or other suitable electronic device.

The host device 108 communicates with a memory interface that enables reading from the memory device 104 and writing to the memory device 104. In some examples, the host device 108 may operate in compliance with an industry specification, such as a Universal Flash Storage (UFS) Host Controller Interface specification. In other examples, the host device 108 may operate in compliance with one or more other specifications, such as a Secure Digital (SD) Host Controller specification or other suitable industry specification. The host device 108 may also communicate with the memory device 104 in accordance with any other suitable communication protocol.

The memory device 104 of the data storage device 102 may include a non-volatile memory (e.g., NAND, BiCS family of memories, or other suitable memory). In some examples, the memory device 104 may be any type of flash memory. For example, the memory device 104 may be two-dimensional (2D) memory or three-dimensional (3D) flash memory. The memory device 104 may include one or more memory dies 103. Each of the one or more memory dies 103 may include one or more memory blocks 112 (e.g., one or more erase blocks). Each memory block 112 may include one or more groups of storage elements, such as a representative group of storage elements 107A-107N. The group of storage elements 107A-107N may be configured as a wordline. The group of storage elements 107A-107N may include multiple storage elements (e.g., memory cells that are referred to herein as a “string”), such as a representative storage elements 109A and 109N, respectively.

The memory device 104 may include support circuitry, such as read/write circuitry 140 to support operation of the one or more memory dies 103. Although depicted as a single component, the read/write circuitry 140 may be divided into separate components of the memory device 104, such as read circuitry and write circuitry. The read/write circuitry 140 may be external to the one or more memory dies 103 of the memory devices 104. Alternatively, one or more individual memory dies may include corresponding read/write circuitry that is operable to read from and/or write to storage elements within the individual memory die independent of any other read and/or write operations at any of the other memory dies.

The controller 106 is coupled to the memory device 104 (e.g., the one or more memory dies 103) with a bus 105, an interface (e.g., interface circuitry), another structure, or a combination thereof. For example, the bus 105 may include multiple distinct channels to enable the controller 106 to communicate with each of the one or more memory dies 103 in parallel with, and independently of, communication with the other memory dies 103.

The controller 106 is configured to receive data and instructions from the host device 108 and to send data to the host device 108. For example, the controller 106 may send data to the host device 108 using the interface 120, and the controller 106 may receive data from the host device 108 with the interface 120. The controller 106 is configured to send data and commands (e.g., the memory operation 136, which may be a cycle operation of a memory block of the memory device 104) to the memory device 104 and to receive data from the memory device 104. For example, the controller 106 is configured to send data and a program or write command to cause the memory device 104 to store data to a specified address of the memory device 104. The write command may specify a physical address of a portion of the memory device 104 (e.g., a physical address of a word line of the memory device 104) that is to store the data.

The controller 106 is configured to send a read command to the memory device 104 to access data from a specified address of the memory device 104. The read command may specify the physical address of a region of the memory device 104 (e.g., a physical address of a word line of the memory device 104). The controller 106 may also be configured to send data and commands to the memory device 104 associated with background scanning operations, garbage collection operations, and/or wear-leveling operations, or other suitable memory operations.

The controller 106 may include a processor 124, a memory 126, and other associated circuitry. The memory 126 may be configured to store data and/or instructions that may be executable by the processor 124.

The controller 106 may send the memory operation 136 (e.g., a read command) to the memory device 104 to cause the read/write circuitry 140 to sense data stored in a storage element. For example, the controller 106 may send the read command to the memory device 104 in response to receiving a request for read access from the host device 108. In response to receiving the read command, the memory device 104 may sense the storage element 107A (e.g., using the read/write circuitry 140) to generate one or more sets of bits representing the stored data.

Generally, one or more components of the data storage device 102, such as the memory devices 104 and/or the controller 106 are solid state integrated circuit packages. These packages are disposed on a printed circuit board (“PCB”) or other applicable substrates. Often a grid array component is used to maximize the connection points between the package and the substrate.

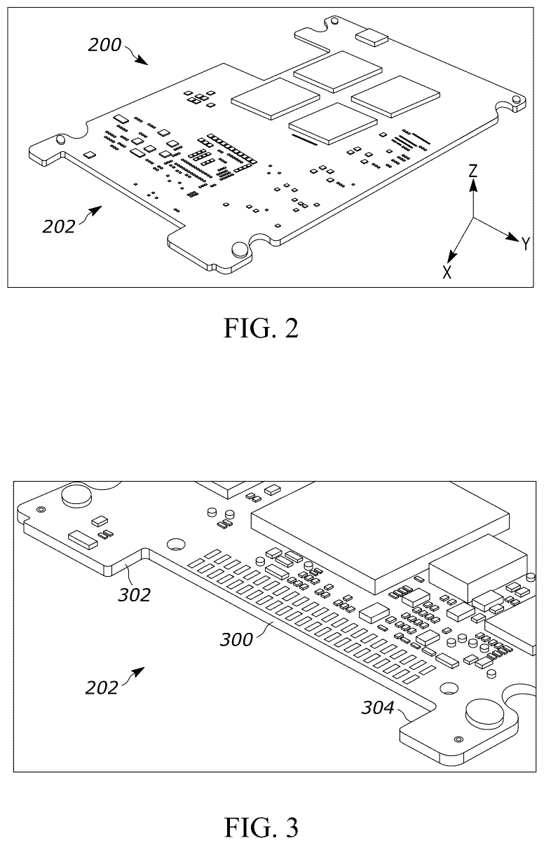

The PCB of the data storage device 102 includes a connector contact area (e.g., the interface 120). The connector contact area complies with PCIe-SIG standards to provide reliable data transmission at high speed. However, comparative PCBs drives end at the connector PCB contact (also referred to as a connector footprint) area, restricting the return current and impeding the shielding of connector contact pads. For example, FIG. 2 is a diagram illustrating a PCB 200 of a comparative data storage device 102. The PCB 200 includes a connector contact area 202, shown in more detail in FIG. 3. As shown in FIG. 3, the connector contact area 202 includes a recessed portion 300 recessed between a first edge portion 302 and a second edge portion 304. The first edge portion 302 and the second edge portion 304 may be, for example, protrusions from a main body of the PCB 200.

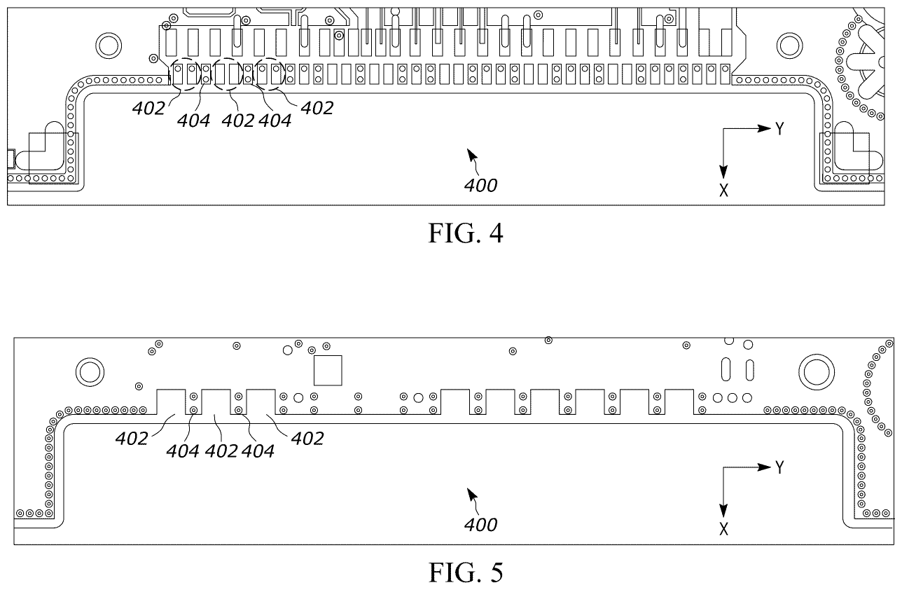

FIG. 4 is a diagram illustrating a plan view of the connector contact area 202 overlaid with the existing U.2 or U.3 connector footprint and ground connectivity as a comparative example. FIG. 5 similarly is a diagram illustrating a plan view of the connector contact area 202 showing the inner reference ground connection voiding and via stitching as a comparative example. The connector contact area 202 includes a plurality of connector contact pads 400 (e.g., connector pins). The connector contact pads 400 are configured in pairs 402, each pair 402 including one transmitting (TX) pin and one receiving (RX) pin. The pairs 402 are separated by a ground pin 404. The ground pin 404 may extend from the main body of the PCB 200. For the sake of clarity, only a portion of the pairs 402 and the ground pins 404 are labeled in FIGS. 4 and 5.

However, this configuration of the plurality of connector contact pads 400 may experience crosstalk interference between the pairs 402 and limit return current flow through the plurality of connector contact pads 400 because the ground pins 404 do not extend beyond edges of the pairs in X-direction. In particular, the crosstalk interference increases as the frequency of the communication signals on the TX and RX pins increases.

Accordingly, examples, aspects, and instances described herein provide a connector PCB contact area that increases return current and shielding of the connector contact pads in the X-direction while complying with PCIe-SIG connector standards. Examples described herein include extending the connector area beyond the recessed portion 300 without disturbing connector placement and mating. Connectors described herein may be, for example, SFF-8639 connectors.

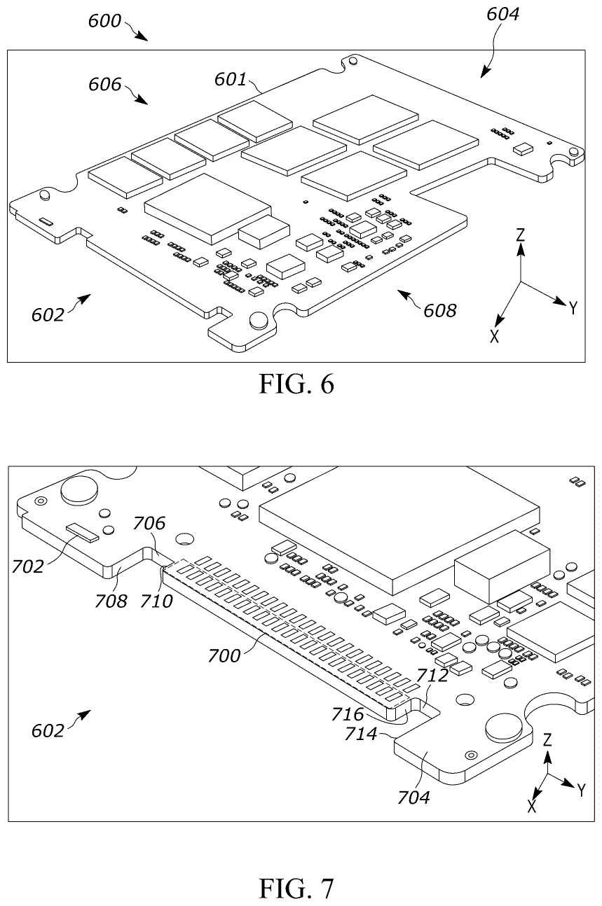

FIG. 6 is a diagram illustrating a PCB 600 of a data storage device 102 having an extension portion according to a comparative example. The PCB 600 includes a main body 601 having a first side 602 (e.g., a connector side, a bottom side) and a second side 604 situated opposite the first side 602. The first side 602 and the second side 604 are connected by a third side 606 and a fourth side 608. The first side 602, the second side 604, the third side 606 and the fourth side 608 collectively form the perimeter of the main body 601.

FIG. 7 illustrates the first side 602 in more detail. The first side 602 includes a connector contact area 700 (indicated by a dashed line) situated between a first protrusion 702 (e.g., a first tab) and a second protrusion 704 (e.g., a second tab). A first recess 706 is formed between the connector contact area 700 and the first protrusion 702 and is defined by a side wall 708 of the first protrusion 702 and a first side wall 710 of the connector contact area 700. A second recess 712 is formed between the connector contact area 700 and the second protrusion 704 and is defined by a side wall 714 of the second protrusion 704 and a second side wall 716 of the connector contact area 700. The first side wall 710 and the second side wall 716 each define a distance of a protrusion portion (or extension) of the connector contact area 700 from a first protrusion and a second protrusion, respectively.

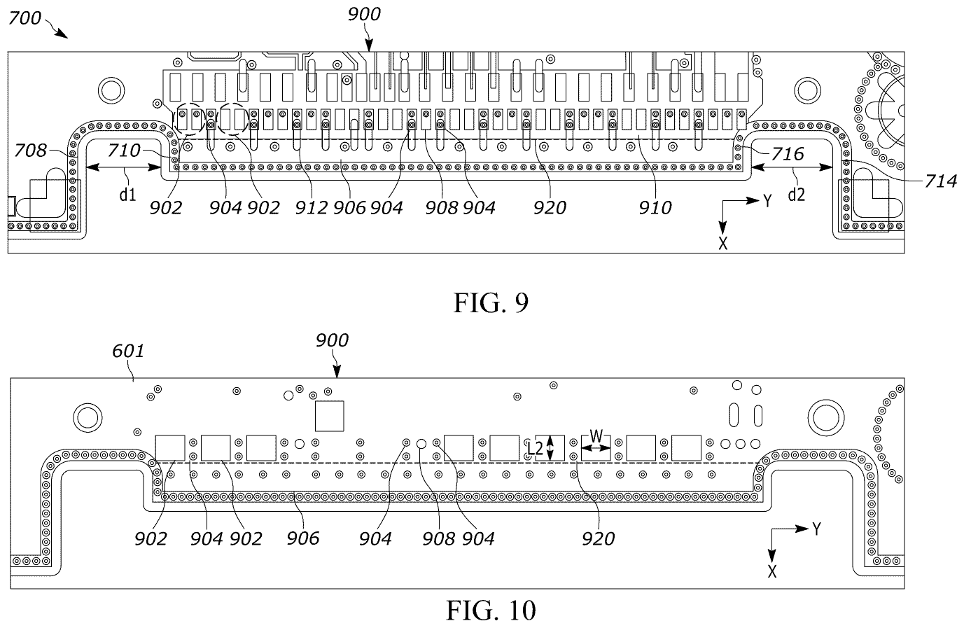

A first distance d1 (shown in FIG. 9) between the side wall 708 and the first side wall 710 may be between approximately 4.0 mm and 5.0 mm, between 4.0 mm and 4.5 mm, between 4.2 mm and 4.4 mm, between 4.21 mm to 4.41 mm, or the like (for example, 4.31 mm). A second distance d2 (shown in FIG. 9) between the side wall 714 and the second side wall 716 may be between approximately 4.0 mm and 5.0 mm, between 4.0 mm and 4.5 mm, between 4.2 mm and 4.4 mm, between 4.21 mm and 4.41 mm, or the like (for example, 4.31 mm). In some instances, the first distance d1 and the second distance d2 are the same. In other instances, the first distance d1 and the second distance d2 are different.

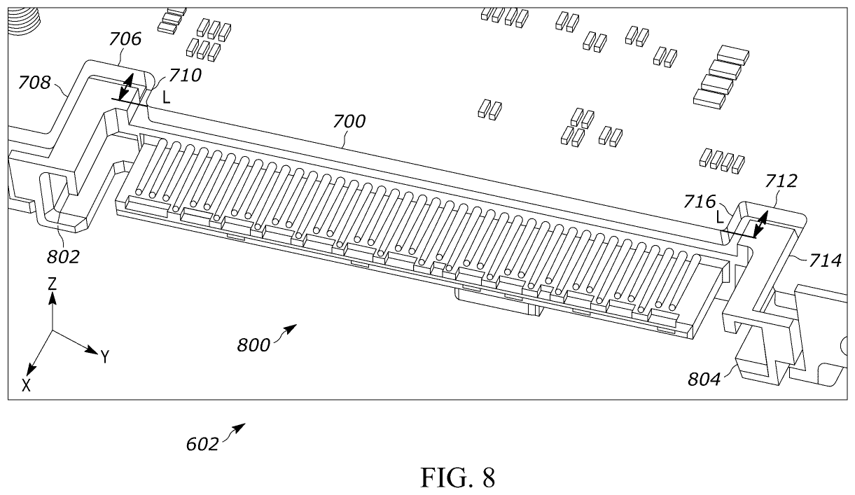

As shown in FIG. 8, the first side wall 710 has a length of L, which may be between a range of 2.0 mm to 3.0 mm, 2.0 mm to 2.5 mm, between 2.1 mm and 2.4 mm, between 2.15 mm and 2.35 mm, or the like (for example, 2.25 mm). The second side wall 716 also has a length of L. In some implementations, shown in FIG. 8, the connector contact area 700 includes a plurality of male connector pins 800 directly adjacent to and protruding away from the connector contact area 700 in a direction perpendicular to a surface of the main body 601 (e.g., in the X-direction). The plurality of male connector pins 800 may correspond to a U.2 or a U.3 male connector. The plurality of male connector pins 800 are configured to mate with a corresponding interface (e.g., female connectors) of a host device (for example, the host device 108). The plurality of male connector pins 800 form an electrical connection between the PCB 600 and the host device 108 when the plurality of male connector pins 800 are received by the corresponding interface of the host device 108. In some implementations, the plurality of male connector pins 800 are electrically connected to a plurality of connector contact pads 900 (which are shown in FIG. 9). The first side 602 may also include one or more mechanical interfaces for mechanical connection between the PCB 600 and the host device 108, such as first mechanical interface 802 and second mechanical interface 804. In some instances, the first mechanical interface 802 and the second mechanical interface 804 may alternatively or additionally function as a ground connection between the PCB 600 and the host device 108.

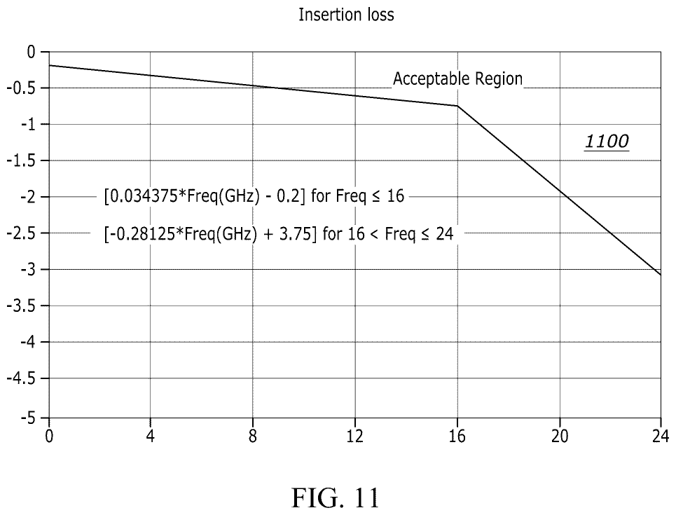

FIG. 9 is a diagram illustrating a plan view of the connector contact area 700 with a connector footprint and ground connectivity. FIG. 9 provides a view of protrusion gap details of the connector contact area 700. FIG. 10 similarly is a diagram illustrating a plan view of the connector contact area 700 with the inner reference ground connection voiding and via stitching. The connector contact area 700 includes a plurality of connector contact pads 900 (e.g., connector pins). The connector contact pads 900 are configured in pairs 902, each pair 902 including one transmitting (TX) pin and one receiving (RX) pin. The pairs 902 are separated by a ground pin 904. For example, a ground pin 904 is located on each side of the pairs 902 (e.g., each pair 902 is adjacent to a ground pin 904). The ground pin 904 may extend from the main body 601 of the PCB 600. The plurality of connector contact pads 900 may also include one or more clock pins 908 situated between two ground pins 904. The plurality of connector contact pads 900 may be, for example, a U.2 SFF-8639 port.

As previously noted, the connector contact area 700 extends from the main body 601 of the PCB 600 (which differs from the comparative PCB 200 illustrated in FIGS. 2-3). With reference to FIGS. 9 and 10, this extension provides for a shielding portion 906 (e.g., a ground shielding vias, a Faraday cage vias) that surrounds the pairs 902 and the clock pins 908 with ground along in at least four directions (while providing a recess for receiving pins of the host device 108). In the example of FIGS. 9-10, the shielding portion 906 is separated from the connector contact pads 900 as illustrated by a dashed line. The ground pins 904 extend from the main body 601 of the PCB 600 toward the shielding portion 906 (shown in FIG. 10). In some implementations, the ground pins 904 are connected to the shielding portion 906 with a through hole via 912. The pairs 902 and the clock pins 908 are separated from the shielding portion 906 by an air gap 910. The air gap 910 may define a distance between the pairs 902 (or the clock pins 908) and the shielding portion 906 of between approximately 0.3 mm to 0.5 mm (for example, 0.4 mm).

As shown in FIG. 10, the pairs 902 have a void width (e.g., the width below the pins) W (measured in the y-direction) and a length L2 (measured in the x-direction). The void width W may be, for example, between approximately 1.7 mm to 2.1 mm, 1.8 mm to 2.1 mm, 1.8 mm to 2.0 mm, or the like (for example, 1.9 mm). The length L2 may be, for example, between approximately 1.4 mm and 1.7 mm, 1.5 mm to 1.6 mm, or the like (for example, 1.55 mm). For the sake of clarity, only a portion of the pairs 902, the ground pins 904, the clock pins 908, and through hole vias 912 are labeled in FIGS. 9 and 10.

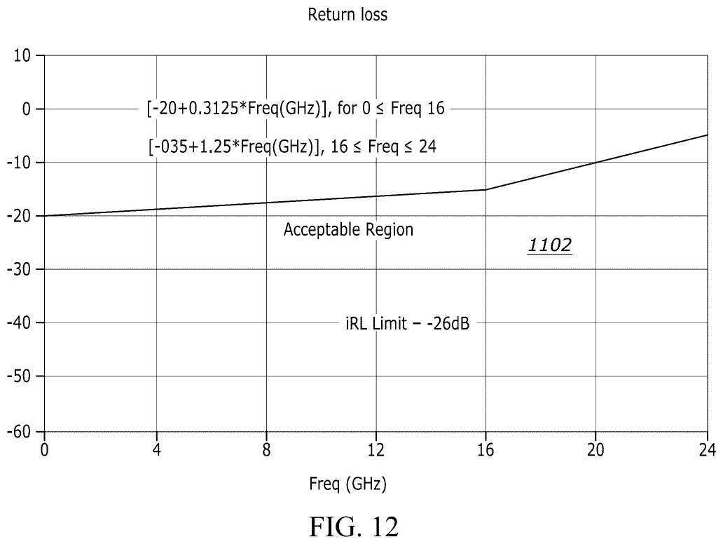

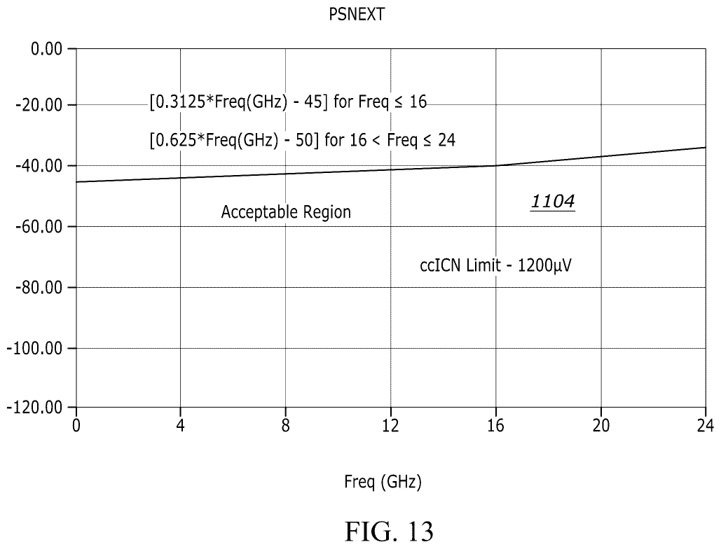

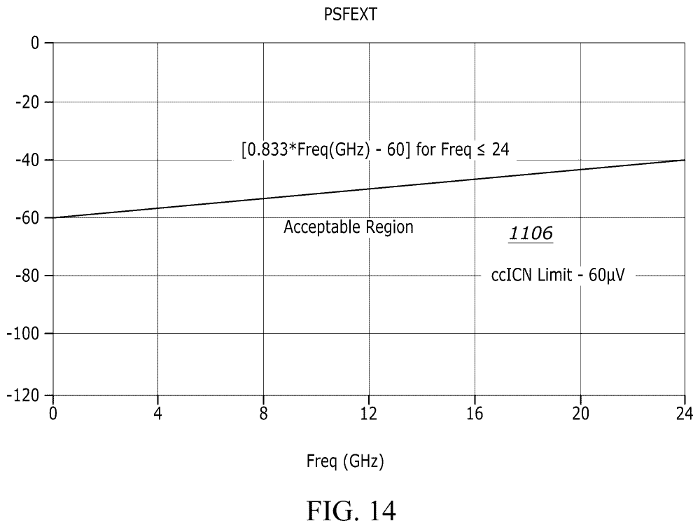

FIGS. 11, 12, 13, and 14 illustrate graphed characteristics and acceptable operating regions for the PCIE5 SFF-8639 SI specification standard. FIG. 11 illustrates an acceptable operating region 1100 for insertion losses. FIG. 12 illustrates an acceptable operating region 1102 for return losses. FIG. 13 illustrates an acceptable operating region 1104 for troublesome near-end cross-talk. FIG. 14 illustrates an acceptable operating region 1106 for troublesome far-end cross-talk.

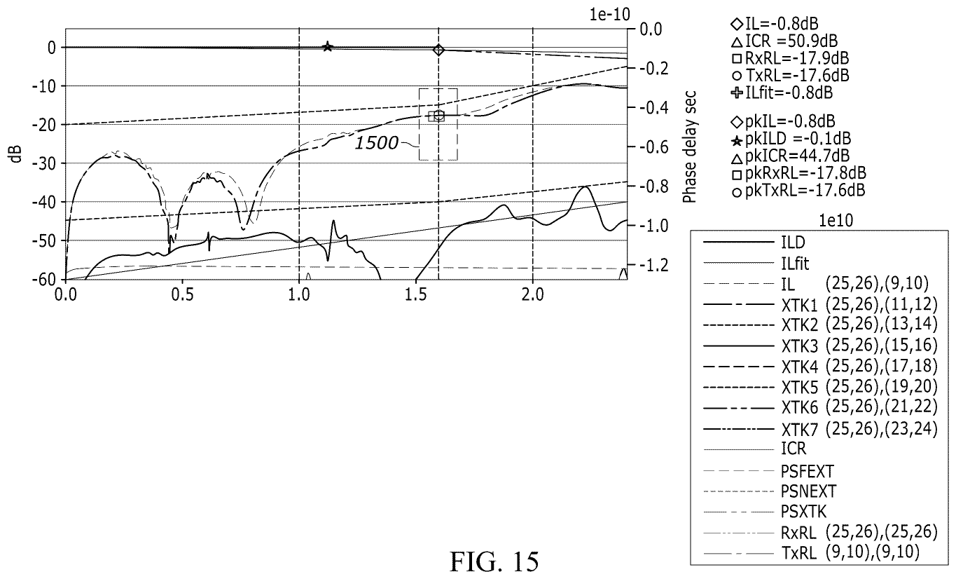

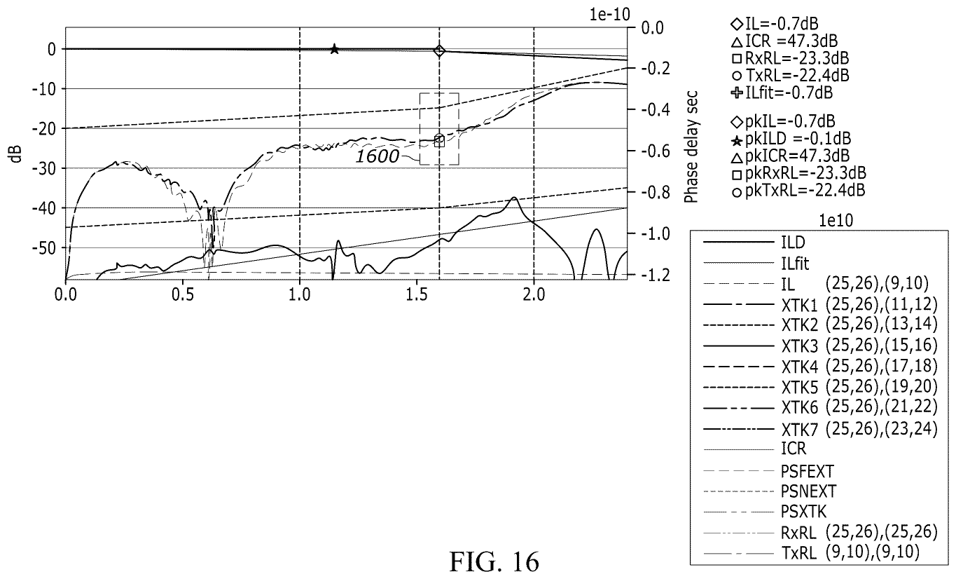

FIG. 15 is chart illustrating a plot of the frequency domain results of a comparative PCIe Gen5 U.2 SFF-8639 connector without the extension portion (e.g., the PCB 200) compared to the graphed characteristics of FIGS. 11, 12, 13, and 14. FIG. 16 is chart illustrating a plot of the frequency domain results of a U.2 SFF-8639 connector with the extension portion (e.g., the PCB 600) compared to the graphed characteristics of FIGS. 11, 12, 13, and 14. In the example of FIG. 15 related to the PCB 200, the Rx losses are −17.9 dB and the Tx losses are −17.6 dB (shown in region of interest 1500). In the example of FIG. 16 related to the PCB 600, these losses are reduced, as the Rx losses are −23.3 dB and the Tx losses are −22.4 dB (shown in region of interest 1600). The PCB 600 also provides for other improvements over the comparable PCB 200. For example, while the PCB 200 allows for 1.5 dB of insertion loss at 8 GHz, the PCB 600 allows for approximately 0.8 dB of insertion loss at 16 GHz. The PCB 600 also provides approximately a 30% improvement in return loss and approximately a 12.50% improvement in insertion loss compared to the PCB 200.

Embodiments described herein primarily refer to PCIe Gen 5 U.2 (or U.3) connectors. However, the PCB 600 and described features of the PCB 600 may be implemented in other connectors, such as PCIe Gen 4 connectors and PCIe Gen 6 connectors.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain implementations and should in no way be construed to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The Abstract is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A solid state memory comprising:
a printed circuit board for a solid state memory, the printed circuit board including:
a main body; and
a connector contact portion at a first end of the main body, the connector contact portion including:
a plurality of pins; and
an extension portion that provides ground shielding to the plurality of pins.

2. The solid state memory of claim 1,
wherein the plurality of pins includes individual transmission (TX) pins paired with individual receiving (RX) pins, wherein at least one pair of a TX pin and an RX pin is adjacent to a first ground pin and a second ground pin.

3. The solid state memory of claim 2, wherein the first ground pin and the second ground pin are connected to the extension portion by a through hole via.

4. The solid state memory of claim 2, wherein each TX/RX pin pair has a width of between approximately 1.8 mm to 2.1 mm, and wherein each TX/RX pin pair has a length of approximately 1.5 mm to 1.6 mm.

5. The solid state memory of claim 1, wherein the plurality of pins and the extension portion are separated by an air gap.

6. The solid state memory of claim 5, wherein the air gap defines a distance between the plurality of pins and the extension portion of between approximately 0.3 mm to 0.5 mm.

7. The solid state memory of claim 1, wherein the first end of the main body includes a first protrusion and a second protrusion, and wherein the connector contact portion is situated between the first protrusion and the second protrusion.

8. The solid state memory of claim 7, wherein the connector contact portion is separated from the first protrusion by a distance between approximately 4.0 mm and 4.5 mm.

9. The solid state memory of claim 1, wherein the extension portion extends from the main body by a distance between approximately 2.0 mm and 2.5 mm.

10. The solid state memory of claim 1, wherein the connector contact portion is connected to an SFF-8639 port.

11. A solid state memory device (SSD) connector comprising:
a connector contact portion including:
a plurality of pins; and
an extension portion that provides ground shielding to the plurality of pins,
wherein the SSD connector is one of a U.2 connector and a U.3 connector.

12. The SSD connector of claim 11, wherein the plurality of pins includes individual transmission (TX) pins paired with individual receiving (RX) pins, wherein at least one pair of a TX pin and an RX pin is adjacent to a first ground pin and a second ground pin.

13. The SSD connector of claim 12, wherein the first ground pin and the second ground pin are connected to the extension portion by a through hole via.

14. The SSD connector of claim 11, wherein the plurality of pins and the extension portion are separated by an air gap.

15. The SSD connector of claim 11, wherein the connector contact portion is connected to an SFF-8639 port.

16. An SFF-8639 connector for a solid state drive (SSD), the connector comprising:
an extension portion extending beyond a plurality of pins,
wherein the plurality of pins are integrated in a connector contact portion of the connector,
wherein the extension portion is an extension of the connector contact portion, and
wherein the extension portion provides ground shielding to the plurality of pins.

17. The connector of claim 16, wherein the plurality of pins includes individual transmission (TX) pins paired with individual receiving (RX) pins, wherein at least one pair of a TX pin and an RX pin is adjacent to a first ground pin and a second ground pin.

18. The connector of claim 17, wherein the first ground pin and the second ground pin are connected to the extension portion by a through hole via.

19. The connector of claim 16, wherein the plurality of pins and the extension portion are separated by an air gap.

20. The connector of claim 16, further comprising:
a mechanical connection interface configured to provide a mechanical connection to a host device.
